(19) United States
(12) Patent Application Publication
(10) Pub. No.: US 2026/0162710 A1
(43) Pub. Date: Jun. 11, 2026

(54) COMMAND DECODER MASKING CIRCUITRY

(71) Applicant: Micron Technology, Inc., Boise, ID (US)

(72) Inventor: Alex Joseph Kozlosky, Decatur, GA (US)

(21) Appl. No.: 19/367,403

(22) Filed: Oct. 23, 2025

Related U.S. Application Data
(60) Provisional application No. 63/730,682, filed on Dec. 11, 2024.

(51) Int. Cl. G11C 11/4096; G11C 11/4076; G11C 11/4078

(52) U.S. Cl. CPC G11C 11/4096; G11C 11/4076; G11C 11/4078

(57) ABSTRACT

Systems and methods described herein include a memory device that includes an interface and masking circuitry. The interface may receive one or more command signals. The masking circuitry may include one or more logic gates that disable propagation of unstable data resulting from unintended signal propagation arising from the one or more command signals.

### CROSS-REFERENCE TO RELATED APPLICATION

This application claims priority to U.S. Provisional Application No. 63/730,682, filed December 11, 2024, which is hereby incorporated by reference in its entirety.

### BACKGROUND

### Field of the Present Disclosure

Embodiments of the present disclosure relate generally to the field of command signal generation and propagation within memory devices. More specifically, embodiments of the present disclosure relate to operations associated with a command decoder of a memory device.

### Description of Related Art

The following generally relates to electronic devices and, more specifically, to memory devices used with various electronic devices. An electronic device may include a memory device, a processing device, and routing circuitry, among other things. For example, the memory device may include a number of memory arrays including memory cells, a row decoder, and a column decoder, among other memory components, to perform memory operations instructed via a memory controller, including memory read and write operations. Moreover, various circuit components of the electronic device, including the memory components, may provide one or more signals for performing the memory operations. For example, semiconductor devices (e.g., memory devices) utilize data signals, data strobes, and/or other signals to perform operations (e.g., write operations).

Over time, it may be desired to provide such signals at increasingly faster speeds to enable faster data processing and memory access speeds. However, in doing so, some signals may experience metastability, or instability in value between readable logic levels. Metastable signals may propagate to a downstream circuit, which may lead to otherwise undesirable operations or effects in the downstream circuit.

Embodiments of the present disclosure may be directed to one or more of the problems set forth above.

### BRIEF DESCRIPTION OF DRAWINGS

FIG. 1 is a simplified block diagram illustrating certain features of a memory device having decision feedback equalizer (DFE) circuitry that includes a DFE that determines a level for data received at the memory device and includes DFE reset circuitry, in accordance with an embodiment;

FIG. 2 is a timing diagram of a mode register write control word signal simulated as experiencing metastability, in accordance with an embodiment; and

FIG. 3 is a block diagram of example command decoder masking circuitry, in accordance with an embodiment.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Semiconductor devices, such as memory devices, may use signals like data signals, command signals, command address signals, data strobes, and the like when performing or enabling operations. In a memory device, these operations may include read operations, write operations, and refresh operations, among other operations. Certain operations may be enabled through different combinations of signals, such as respective combinations of command and command address signals, clocking signals, enable bits, and the like. Furthermore, it may be desirable to provide such signals at increasingly faster speeds to enable increasingly faster data processing and memory access speeds. However, in doing so, some signals may experience metastability, or instability in value between readable logic levels, as different combinations of commands interact with one another and/or with material properties of the memory device components. In some systems, depending on technical specifications the system is being manufactured according to, the metastability is not desired and is to be avoided. Indeed, such a metastable signal may be propagated through memory device components to a downstream circuit, which may lead to otherwise undesirable operations or effects in the downstream circuit.

Such a memory device may be a DDR5 memory device. For example, DDR5 memory devices may increase operational rates through various improvements, including performing write operations consecutively such that data entry is gapless between two consecutive writes. While these operations may enable relatively greater data rates and command processing operations relative to other generations of memory devices and/or architectures, this relatively faster operation may increase a risk of metastable signals being propagated from a command decoder.

One such example of when metastable signals may be propagated from a command decoder of a memory device is during a reset period of the memory device. During a reset period, there may be a relatively long delay (e.g., one or more clock cycles) between a change in signal on an external reset pin of the command decoder and a change in signal on an internal reset pin of the command decoder. During this period, declarations of command address pins of the command decoder may be permitted. Validation testing has revealed that a mode register write control word (MRW_CW) signal instability may cause potential undesirable operations or effects downstream from the command decoder. The instability in MRW_CW may occur during a relatively small gap in timing between even and odd latched command signals during the reset period due to command address pin declarations.

To elaborate, a reset period may correspond to a time period between consecutive commands in which one or more portions of a memory device undergo a reset. When a reset occurs, some circuitry of the memory device may expect no signals being output from the command decoder. A metastable signal may nonetheless be propagated to downstream circuitry from the command decoder during the reset when a signal instability occurs. Thus, including circuitry in the command decoder to reduce or eliminate a likelihood of the metastable signal propagating to any circuitry may be desired.

As discussed herein, the command decoder may be coupled to or include masking circuitry. The command decoder masking circuitry may include one or more logic gates that selectively block, or mask, a command word when the command word is metastable. The one or more logic gates may disable the propagation of unstable signals, like data signals, on a command word output path from the command decide arising from errant commands issued during the reset. One such circuitry is described herein, which may resolve or reduce a likelihood of metastability of the MRW_CW signal during a reset period prior to propagation through the masking of the mode register write control word signal relative to even and odd command latch signals.

Command decoder masking circuitry may maintain stability of control word commands being transmitted to a mode register regardless of whether a combination of preceding commands are issued leading into the reset. Indeed, through disabling propagation of unstable signals on the command word output path, the command decoder masking circuitry may reduce or eliminate a likelihood of undesired operations occurring in or due to downstream circuits operationally responding to the unstable signals. Additionally, these technical improvements may be realized through the command decoder masking circuitry with negligible changes to propagation delays and circuitry footprint within a die or physical space of the memory device.

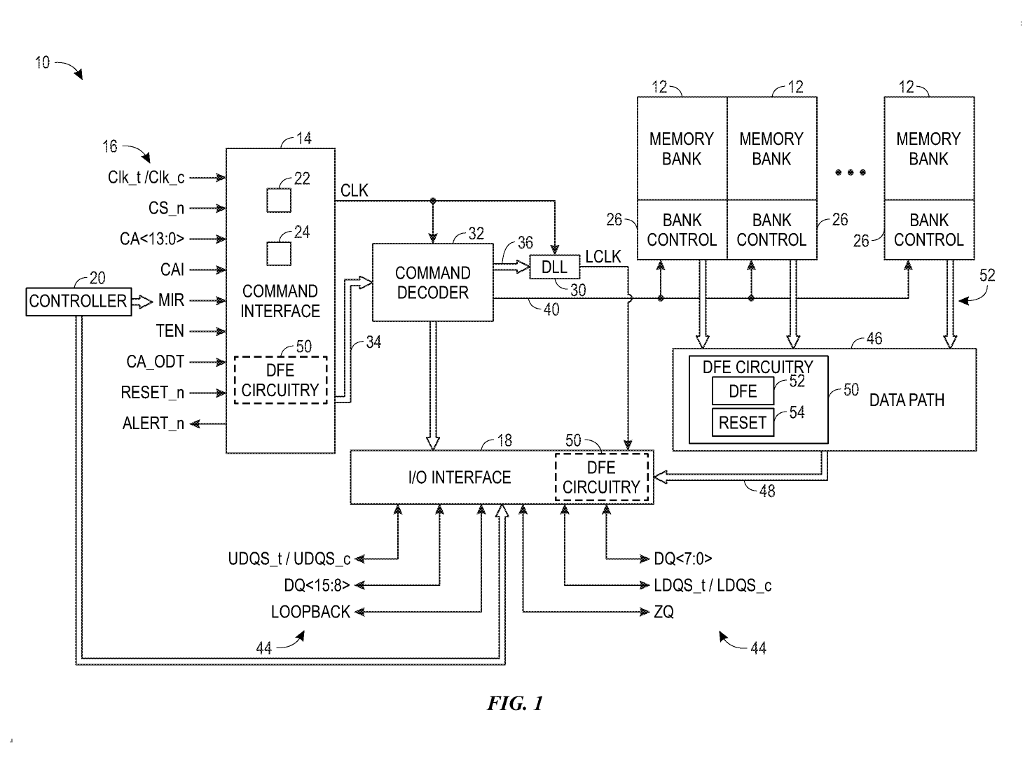

Turning now to the figures, FIG. 1 is a simplified block diagram illustrating certain features of a memory device 10. Specifically, the block diagram of FIG. 1 is a functional block diagram illustrating certain functionality of the memory device 10. In accordance with one embodiment, the memory device 10 may be a double data rate type five synchronous double data rate dynamic random access memory (DDR5 SDRAM) device. Various features of DDR5 SDRAM may permit reduced power consumption, more bandwidth, and more storage capacity compared to prior generations of DDR SDRAM.

The memory device 10, may include a number of memory banks 12. The memory banks 12 may be DDR5 SDRAM memory banks, for instance. The memory banks 12 may be provided on one or more chips (e.g., SDRAM chips) that are arranged on dual inline memory modules (DIMMs). Each DIMM may include a number of SDRAM memory chips (e.g., x8 or x16 memory chips), as will be appreciated. Each SDRAM memory chip may include one or more memory banks 12. The memory device 10 represents a portion of a single memory chip (e.g., SDRAM chip) having a number of memory banks 12. For DDR5, the memory banks 12 may be further arranged to form bank groups. For instance, for an 8 gigabit (Gb) DDR5 SDRAM, the memory chip may include 16 memory banks 12, arranged into 8 bank groups, each bank group including 2 memory banks. For a 16 Gb DDR5 SDRAM, the memory chip may include 32 memory banks 12, arranged into 8 bank groups, each bank group including 4 memory banks, for instance. Various other configurations, organization and sizes of the memory banks 12 on the memory device 10 may be utilized depending on the application of the overall system. Furthermore, DDR5 SDRAM configurations are discussed by way of example, but it is understood that various other memory specifications such as past and evolving DDR and low power DDR (LPDDR) configurations have similar functions and may likewise benefit from the circuits and methods described herein. As such depending upon the specific DDR specification, various components of FIG. 1 may be altered to comply with the specification.

The memory device 10 may include a command interface 14 and an input/output (I/O) interface 18. The command interface 14 may receive a number of signals (e.g., signals 16, signals 44) from an external device, such as a controller 20. The controller 20 may include processing circuitry. The controller 20 may be a memory controller. The controller 20 may generate and provide various signals 16, 44 to the memory device 10. The signals 44 may include DQ and/or DQS signals. The controller 20 may communicate with the memory device 10 using the signals 16, 44. Thus, the signals 16, 44 may facilitate the transmission and receipt of data to be written to or read from the memory device 10.

As an example of signals 16, the processor or controller may request a read and/or write operation by providing the corresponding command and an address via the CA bus. A chip select (CS) enable signal (e.g., CS_n signal) may be held high (e.g., logical high, logical high voltage level) by the processor or controller when the command is provided by the processor or controller.

The command interface 14 may include a number of circuits, such as a clock input circuit 22 and a command address input circuit 24, for instance, to permit proper handling of the signals 15. The command interface 14 may receive one or more clock signals from an external device. Generally, double data rate (DDR) memory utilizes a differential pair of system clock signals, referred to as the true clock signal (Clk_t) and the complementary clock signal (Clk_c). The positive clock edge for DDR refers to the point where the rising true clock signal (Clk_t) crosses the falling complementary clock signal (Clk_c), while the negative clock edge indicates that transition of the falling true clock signal (Clk_t) and the rising of the complementary clock signal (Clk_c). Commands (e.g., read command, write command, refresh command) are typically entered on the positive edges of the clock signal and data is transmitted or received on both the positive and negative clock edges.

The clock input circuit 22 may receive the true clock signal (Clk_t) and the complementary clock signal (Clk_c) and may generate an internal clock signal (CLK). The internal clock signal (CLK) may be supplied to an internal clock generator 30, such as a delay locked loop (DLL) circuit. The internal clock generator 30 generates a phase controlled internal locked clock signal (LCLK) based on the received internal clock signal (CLK). The phase controlled internal locked clock signal (LCLK) is supplied to the I/O interface 18, for instance, and is used as a timing signal for determining an output timing of read data.

The internal clock signal (CLK) may also be provided to various other components within the memory device 10 and may be used to generate various additional internal clock signals. For instance, the internal clock signal (CLK) may be provided to a command decoder 32. The command decoder 32 may receive command signals from the command/address (CA) bus 34 and may decode the command signals to provide various internal commands. For instance, the command decoder 32 may provide command signals to the internal clock generator 30 over the bus 36 to coordinate generation of the phase controlled internal locked clock signal (LCLK). The phase controlled internal locked clock signal (LCLK) may be used to clock data through the I/O interface 18, for instance.

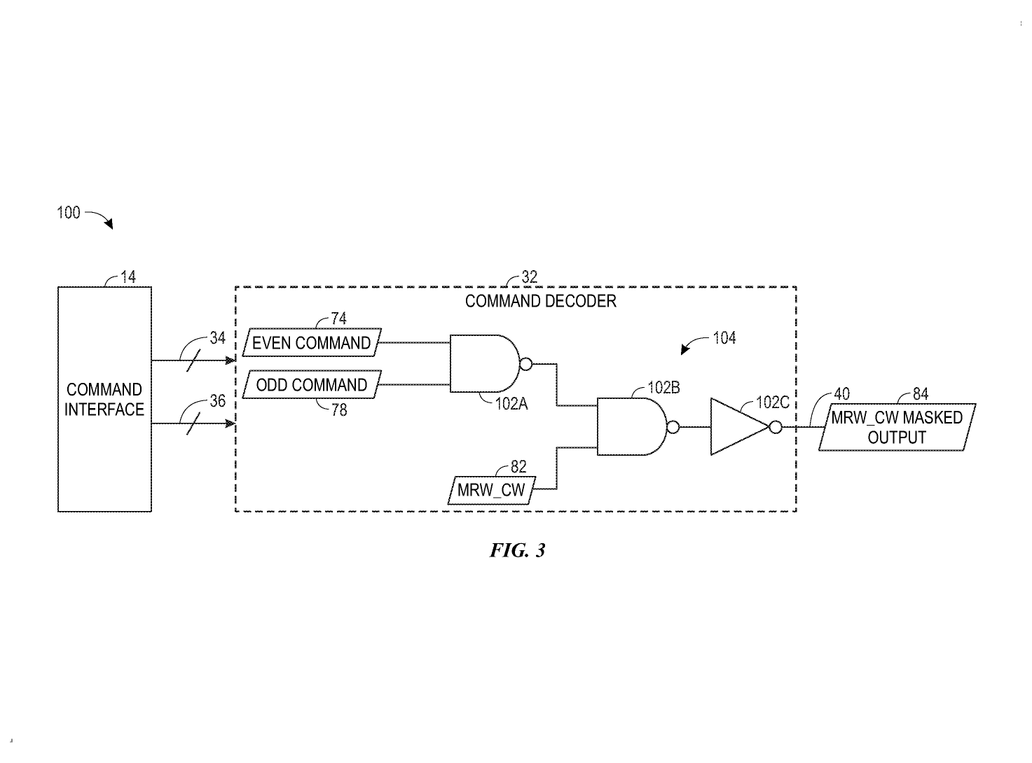

The command decoder 32 may decode commands, such as read commands, write commands, mode-register set commands, activate commands, or the like, and provide access to a particular memory bank 12 corresponding to the command, via the bus 40. The command decoder 32 may include masking circuitry operable to disable propagation of one or more unstable signals, such as masking circuitry illustrated in FIG. 3. The masking circuitry may transmit stable signals via the bus 40 as an output path from the command decoder 32 to downstream circuitry, such as bank control circuitry 26 and/or one or more mode registers of the bank control circuitry 26. In some systems, the command decoder 32 and the masking circuitry are disposed on a same die, such as a die of the memory device 10. In some cases, the controller 20 is disposed on a different die than the command decoder 32.

The memory device 10 may include various other decoders, such as row decoders and column decoders, to facilitate access to the memory banks 12. In one embodiment, each memory bank 12 includes a bank control circuitry 26 which provides the necessary decoding (e.g., row decoder and column decoder), as well as other operations, such as timing control and data control, to facilitate the execution of commands to and from the memory banks 12. Collectively, the memory banks 12 and the bank control circuitry 26 may be referred to as a memory array.

The memory device 10 executes operations, such as read commands and write commands, based on the command/address signals received from an external device, such as a processor. In one embodiment, the command/address bus may be a 14-bit bus to accommodate the command/address signals (CA<13:0>). The command/address signals are clocked to the command interface 14 using the clock signals (Clk_t and Clk_c). The command interface may include a command address input circuit 24. The command address input circuit 24 may be configurable to receive and transmit the commands to provide access to the memory banks 12, through the command decoder 32, for instance. In addition, the command interface 14 may receive a chip select signal (CS_n). The CS_n signal may cause the memory device 10 to process commands on the incoming CA<13:0> bus. Access to specific memory banks 12 within the memory device 10 is encoded on the CA<13:0> bus with the commands.

In addition, the command interface 14 may receive a number of other command signals. For instance, a command/address on die termination (CA_ODT) signal may be provided to facilitate proper impedance matching within the memory device 10. A reset command (RESET_n) may be used to reset the command interface 14, status registers, state machines and the like, during power-up for instance. The command interface 14 may also receive a command/address inverted (CAI) signal which may be provided to invert the state of command/address signals CA<13:0> on the command/address bus, for instance, depending on the command/address routing for the particular memory device 10. A mirror (MIR) signal may also be provided to facilitate a mirror function. The MIR signal may be used to multiplex signals. This may swap the signals to enable certain routing of signals to the memory device 10, based on the configuration of multiple memory devices in a particular application. Various signals to facilitate testing of the memory device 10, such as the test enable (TEN) signal, may be provided, as well. For instance, the TEN signal may be used to place the memory device 10 into a test mode for connectivity testing.

The command interface 14 may transmit a first command signal and a second command signal at an overlapping time. The transmission may be via the bus 34. The first command signal and/or the second command signal may be associated with address signals. The first command signal may be associated with an odd command count or occurrence of generation and the second command signal may be associated with an even command count or occurrence.

The command interface 14 may also be used to provide an alert signal (ALERT_n) to the system processor or controller for certain errors that may be detected. For instance, an alert signal (ALERT_n) may be transmitted from the memory device 10 if a cyclic redundancy check (CRC) error is detected. Other alert signals may also be generated. Further, the bus and pin for transmitting the alert signal (ALERT_n) from the memory device 10 may be used as an input pin during certain operations, such as the connectivity test mode executed using the TEN signal, as described above.

Data may be sent to and from the memory device 10, utilizing the command and clocking signals discussed above, by transmitting and receiving data signals 44 through the I/O interface 18. More specifically, the data may be sent to or retrieved from the memory banks 12 over the data path 46, which includes multiple bi-directional data buses. Data I/O signals, generally referred to as DQ signals, are generally transmitted and received in one or more bi-directional data buses. The data path 46 may convert the DQ signals from a serial bus 48 to a parallel bus 56.

For certain memory devices, such as a DDR5 SDRAM memory device, the data I/O signals may be divided into upper and lower bytes. For instance, for a x16 memory device, the data I/O signals may be divided into upper and lower data I/O signals (e.g., DQ<15:8> and DQ<7:0>) corresponding to upper and lower bytes of the data signals, for instance.

To permit higher data rates within the memory device 10, certain memory devices, such as DDR memory devices may utilize data strobe signals, generally referred to as data strobe (DQS) signals. The DQS signals are driven by the external processor or controller sending the data (e.g., for a write command) or by the memory device 10 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the DQS signals may be provided as a differential pair of data strobe signals (DQS_t and DQS_c) to provide differential pair signaling during reads and writes. For certain memory devices, such as a DDR5 SDRAM memory device, the differential pairs of DQS signals may be divided into upper and lower data strobe signals (e.g., UDQS_t and UDQS_c; LDQS_t and LDQS_c) corresponding to upper and lower bytes of data sent to and from the memory device 10, for instance.

An impedance (ZQ) calibration signal may also be provided to the memory device 10 through the I/O interface 18. The ZQ calibration signal may be provided to a reference pin and used to tune output drivers and ODT values by adjusting pull-up and pull-down resistors of the memory device 10 across changes in process, voltage and temperature (PVT) values. Because PVT characteristics may impact the ZQ resistor values, the ZQ calibration signal may be provided to the ZQ reference pin to be used to adjust the resistance to calibrate the input impedance to known values. As will be appreciated, a precision resistor is generally coupled between the ZQ pin on the memory device 10 and GND/VSS external to the memory device 10. This resistor acts as a reference for adjusting internal ODT and drive strength of the IO pins.

In addition, a loopback signal (LOOPBACK) may be provided to the memory device 10 through the I/O interface 18. The loopback signal may be used during a test or debugging phase to set the memory device 10 into a mode wherein signals are looped back through the memory device 10 through the same pin. For instance, the loopback signal may be used to set the memory device 10 to test the data output of the memory device 10. Loopback may include both a data and a strobe or possibly just a data pin. This is generally intended to be used to monitor the data captured by the memory device 10 at the I/O interface 18.

As will be appreciated, various other components such as power supply circuits (for receiving external VDD and VSS signals), mode registers (to define various modes of programmable operations and configurations), read/write amplifiers (to amplify signals during read/write operations), temperature sensors (for sensing temperatures of the memory device 10), etc., may also be incorporated into the memory device 10. Accordingly, it should be understood that the block diagram of FIG. 1 is only provided to highlight certain functional features of the memory device 10 to aid in the subsequent detailed description.

DDR5 may enable write operations to be performed consecutively such that data entry is gapless between two consecutive writes. This may enable relatively greater data rates and command processing operations relative to other generations of memory devices and/or architectures. To further support the relatively greater data rates, the memory device 10 may include decision feedback equalizer (DFE) circuitry 50. For example, the DFE circuitry 50 may be included in the data path 46, the I/O interface 18, and/or the command interface 14. The DFE circuitry 50 may use one or more DFEs 52 and an input buffer of a number (e.g., 4) of previous bits (e.g., high or low) to interpret incoming data bits in data IO signals, generally referred to as DQ signals. The DFE circuitry 50 uses the previous levels in the DQ signals to increase accuracy of interpreting incoming bits in the DQ signals. The DFE input buffer depends upon tracking the previous input history on the channel to decide which input tap to use for a next data input. In some cases, the DFE circuitry 50 includes DFE reset circuitry 54 to perform the reset of the DFE 52.

With the foregoing in mind, various external resets and internal resets may occur relative to the memory device 10. When resets occur, circuitry downstream from the circuitry being reset may expect no inputs. However, some conditions may lead to signal instabilities within such circuitry during a respective reset, such as a signal received or generated at an input with voltage that is between a logic low voltage and a logic high voltage (e.g., generally, a metastable signal). When such a signal is generated, downstream circuitry may receive the signal through propagation from upstream circuitry and misoperate responsive to the propagated signal based on how the downstream circuitry is otherwise not expecting the input, let alone the input signal not having a value able to be identified as a logic high value or a logic low value.

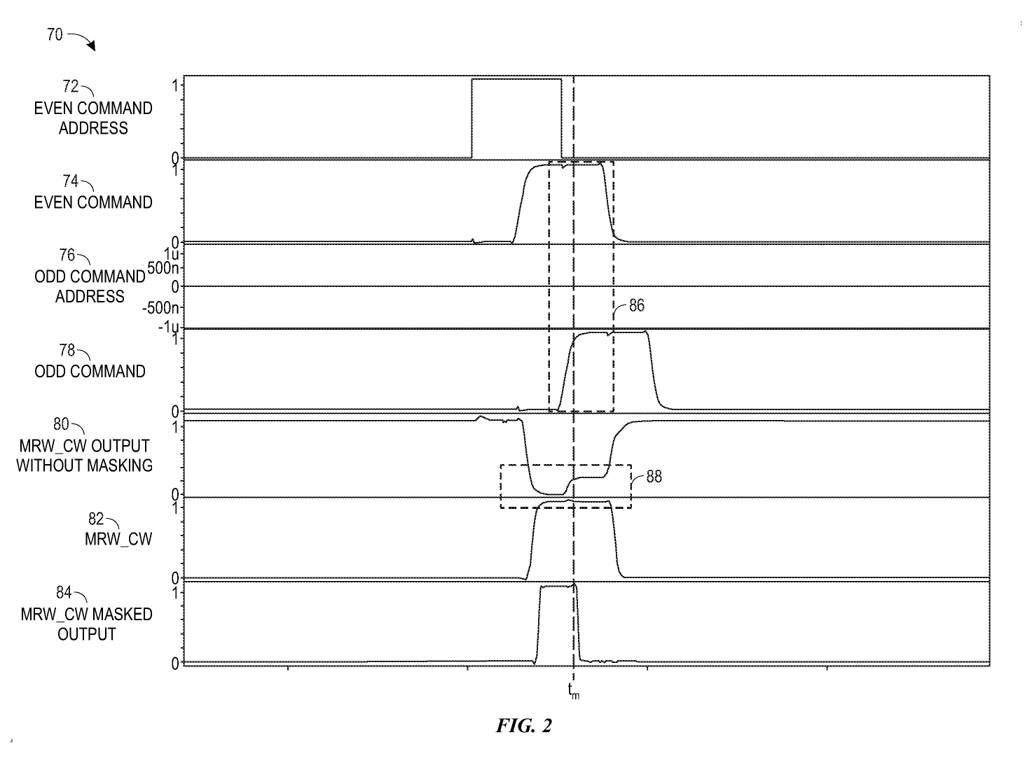

To elaborate, FIG. 2 is a timing diagram 70 that illustrates a simulated signal (e.g., mode register write control word (MRW_CW) signal 80) experiencing metastability arising from overlapping transmissions of even and odd command signals (e.g., even command signal 74 and odd command signal 78). A reset period may be illustrated in the timing diagram 70. During reset, even and odd command latch signals may be triggered one clock cycle apart (e.g., less than or equal to timing of one clock cycle), which may cause an overlap in time (illustrated at indication 86) between receiving respective active high logic levels of the respective even and odd command signals. The even command signal 74 may have a logic high voltage level (corresponding to voltage level of “1”) for a first time period, where the odd command signal 78 has the logic high voltage level for a second time period at least partially overlapping the first time period (illustrated at indication 86). This relatively short time between command triggering leading to the overlap may lead to metastability (illustrated at indication 88) of the MRW_CW signal 80 due to the structure of its corresponding address latch circuitry.

Metastability may occur when particular structures of the memory device 10 interact with each other when signals are transmitted through the memory device 10 structures. This may include material properties of materials physically used to manufacture components disposed on a same die as the memory device 10, material properties of signal paths between components of the memory device 10, capacitive couplings between components of the memory device 10 or embedded circuitry layers of the die or of components of the memory device, or the like. When a signal has instability in its value, the instability could lead to downstream effects. For example, the MRW_CW signal 80 having the metastability (illustrated at indication 88) may lead to an undesired or unexpected operation at one or more mode registers of the bank control circuitry 26, or even in coupled memory bank 12 circuitry control based on the one or more mode registers.

Here, the metastability arises from an overlap in the even command signal 74 and the odd command signal 78. The even command signal 74 is transmitted at a logic high voltage level (e.g., “1”) at an at least partially overlapping time period as the odd command signal 78 being transmitted at the logic high voltage level. An even command address signal 72 may be transmitted in association with the even command signal 74 and may provide a targeted memory address within the memory bank 12 for a command associated with the even command signal 74 to be performed. An odd command address signal 76 may be transmitted in association with the odd command signal 78 and may provide a targeted memory address within the memory bank 12 for a command associated with the odd command signal 78 to be performed. This occurring during the reset period may cause the MRW_CW signal 80 (e.g., MRW_CW output generated without masking circuitry) to experience instability in its voltage value. The instability, or metastability, may cause the voltage value of the MRW_CW signal 80 to fluctuate between logic high voltage level and a logic low voltage level, sometimes settling to a voltage value uninterpretable as either a high or low signal.

Through applying masking circuitry selectively based on the even command signal 74 and the odd command signal 78, the metastability in MRW_CW signal 80 that arises from the overlap of the even command signal 74 and the odd command signal 78 may be mitigated. The mitigation from masking may occur preemptive to the metastability occurring. A MRW_CW signal 82 may be an original mode register control word prior to any masking or metastability. A MRW_CW masked output signal 84 may be a signal generated based on the masking circuitry. The MRW_CW masked output signal 84 may have a falling edge at a time (tₘ) corresponding to a start of an overlap in timing between the even command signal 74 and the odd command signal 78. It is noted that the metastability (illustrated at indication 88) is not present or merely negligibly present in the MRW_CW signal 82, such that any effects from metastability are negligible to circuitry downstream from the command decoder 32.

To elaborate on the masking circuitry, any suitable circuitry may be used to mask a command signal (e.g., the MRW_CW signal 80) to mitigate the potential metastability. Indeed, masking circuitry may receive, via a first logic gate, a first command signal having a logic high voltage level for a first time period. The masking circuitry may receive, via the first logic gate, a second command signal having the logic high voltage level for a second time period, where the second time period may at least partially overlapping in time to the first time period. The masking circuitry may generate, via the first logic gate, a first output signal and may receive, via a second logic gate, the first output signal. The masking circuitry may receive, via the second logic gate, a third command signal. The masking circuitry may generate, via the second logic gate, a second output signal, where the second output signal has a falling edge aligned to a rising edge of the second command signal. This may include generating the second output signal with the falling edge and a rising edge that aligns with a rising edge of the first command signal. The masking circuitry may transmit, via an output pin of the command decoder 32, the second output signal to downstream circuitry, such as a mode register. In some cases, the masking circuitry may receive an enable signal from the controller 20, where the enable signal may enable a first not-AND gate as the first logic gate and a second not-AND gate as the second logic gate. Example masking circuitry is illustrated in FIG. 3, where the third command signal may correspond to a mode register write control word signal and the second output signal may correspond to a mode register write control word masked output signal. Although specific configurations are described herein relative to FIG. 3, it should be understood that a variety of different types of logic gates may supplement or replace one or more logic gates described herein to disable propagation of unstable data resulting from unintended signal propagation arising from one or more command signals received via a memory device interface.

To elaborate, FIG. 3 is a block diagram 100 of an example portion of memory device 10 of FIG. 1, which includes logic gates 102 (e.g., logic gate 102A, logic gate 102B, logic gate 102C) forming example masking circuitry 104. The masking circuitry 104 may be disposed at an output of the command decoder 32. The masking circuitry 104 may be located between the command interface 14 and bank control circuitry 22. Although shown within the command decoder 32, in some systems, the masking circuitry 104 may be disposed externally to the command decoder 32 in the bus 40.

The memory device 10 may include an interface, such as the command interface 14, and masking circuitry, such as the masking circuitry 104. The command interface 14 may receive one or more command signals. The masking circuitry 104 may include one or more logic gates 102 operable to disable propagation of unstable data resulting from unintended signal propagation arising from the one or more command signals.

To elaborate, the controller 20 of FIG. 1 may generate one or more command signals. Indeed, the controller 20 of FIG. 1 may be a memory controller that generates a first command signal and a second command signal sent to the command interface 14. The command interface 14 may receive command and address signals (e.g., one or more signals of the signals 16) from the controller 20 of FIG. 1. The command and address signals may include the even command address signal 72, the even command signal 74, the odd command address signal 76, and the odd command signal 78 of FIG. 2. The command interface 14 may transmit the command and address signals via bus 34. The even command signal 76 may instruct a memory access operation relative to one or more even numbered memory banks 12 or subsets of memory. The odd command signal 78 may instruct a memory access operation relative to one or more odd numbered memory banks 12 or subsets of memory. The command interface 14 may transmit one or more clock signals via bus 36.

The command decoder 32 may receive the clock signals from the bus 36 and the command and address signals from the bus 34. The command decoder 32 may include additional circuitry to process the command and address signals prior to transmission to the bank control circuitry 26 of FIG. 1. In some cases, the command decoder 32 may include the masking circuitry 104 to mitigate metastability in a respective command signal prior to transmission to the bank control circuitry 26.

For example, the command decoder 32 may receive the even command signal 74 from the bus 34. The command decoder 32 may receive the odd command signal 78 from the bus 34. The command decoder 32 may generate a mode register write control word signal (e.g., MRW_CW signal 82) based on one or more command signals and/or one or more address signals. When the controller 20 of FIG. 1 generates these even and odd commands at a time that at least partially overlaps, the masking circuitry 104 may mitigate metastability in the generated MRW_CW signal 82.

While overlapping, both the even command signal 74 and the odd command signal 78 may be transmitted with a logic high voltage level (e.g., “1”) to the logic gate 102A. The logic gate 102A may receive a first command signal as the even command signal 74 and a second command signal as the odd command signal 78. As illustrated, the logic gate 102A may be a not-AND (NAND) gate that outputs a logic low voltage level when both inputs received at its gate terminals are logic high voltage levels. An output voltage from the logic gate 102A transmitted to the logic gate 102B may be a first output signal. While overlapping, the logic gate 102A may transmit a logic low voltage level to the logic gate 102B. Before and after the overlap, the logic gate 102A may transmit a logic high voltage level to the logic gate 102B while one or both inputs received at its gate terminals are logic low voltage levels.

The logic gate 102B may receive the first output signal from a first logic gate (e.g., logic gate 102A) and a third command signal (e.g., MRW_CW signal 82). The logic gate 102B may generate, based on voltages of the first output signal and the third command signal, a masked third command signal (e.g., MRW_CW masked output signal 84). The masked third command signal may have instability removed through the masking enabled by the logic gate 102B and the logic gate 102A. The masked third command signal may be transmitted by the command decoder 32 to downstream circuitry coupled to the bus 40, such as a mode register coupled to the command decoder 32 via the bus 40. The logic gate 102B transmits a logic low voltage level while both inputs (e.g., the first output signal and the third command signal) received at its gate terminals are logic high voltage levels. Thus, the logic gate 102B may transmit a logic low voltage level while both the MRW_CW signal 82 is at a logic high voltage level and the signal transmitted from the logic gate 102A is a logic high voltage level (e.g., before and after the overlapping of the even command signal 74 and the odd command signal 78). This selective transmission through the logic gate 102B may prevent metastability from occurring in the transmitted MRW_CW masked output signal 84, and thus from being propagated to downstream circuitry. For example, bank control circuitry 26 may generate one or more bank control signals based on the transmitted MRW_CW masked output signal 84 from the command decoder 32.

In some systems, the output from the logic gate 102B is inverted. The masking circuitry 104 may be coupled to an output from the command decoder 32 via the logic gate 102C (e.g., an inverting logic gate, an inverter). In systems where the output is not inverted, the logic gate 102C may be excluded in some systems or bypassed. The effect here may be that logic gate 102B may couple to downstream circuitry via bus 40 directly as opposed to being coupled through the logic gate 102C. To generate the MRW_CW masked output signal 84 illustrated in timing diagram 70, the output from the logic gate 102B may bypass the logic gate 102C and not be inverted or else since the MRW_CW signal 82 already is characterized with a logic high level corresponding to a “1” voltage level.

However, some systems may receive the third command signal, such as the MRW_CW signal 82, from a latch. The logic gate 102B input may couple to an output from the latch, where the output transmits the third command signal. At output from the latch, the MRW_CW signal 82 may be inverted such that its logic high level corresponds to a “0” voltage level. An example of the inversion is shown in the MRW_CW signal 80. If MRW_CW signal is inverted at input to the logic gate 102B, such that its logic high level corresponds to a “0” voltage level, the logic gate 102C may be included to re-invert the signal before transmission to bus 40. When inverted, the MRW_CW masked output signal 84 may be transmitted from the command decoder 32 via the logic gate 102C.

In some systems, additional buffering circuitry may be added to other portions of the command decoder 32 or other downstream circuitry to compensate for relatively low amounts of latency added to the command decoding path from the masking circuitry 104. For example, the memory device 10 may include delay circuitry with a delay programmed to compensate timing of one or more command signals based on a latency added to a masked command signal generated via the masking circuitry 104. Furthermore, in some systems, the masking circuitry 104 may be selectively enabled from the controller 20 in FIG. 1 setting a bit, a flag, or otherwise instructing the command decoder 32 to couple the masking circuitry 104 to an output from the command decoder 32. The controller 20 may selectively enable the circuitry in response to determining that there are incoming combinations of commands (e.g., incoming relative to the command decoder 32) that may cause metastability in one or more outputs from the command decoder 32. The masking circuitry 104 being selectively enabled and disabled may reduce power consumed by the memory device 10. The controller 20 may generate or receive indication of the one or more command signals and thus may detect when different combinations of command signals are being sent or are scheduled for sending to the command decoder 32. The controller 20 may detect a combination and compare an indication of the combination to an indication of combinations that are expected to cause metastability. When the expected combination matches a metastability-causing combination, the controller 20 may generate the enable signal to enable the masking circuitry 104 based on a determination to reduce metastability from the expectation that the combination is to cause metastability. Enable circuitry of the masking circuitry 104 may couple the masking circuitry 104 to the bus 34, 36, and 40 in response to the enable signal. Any suitable enable circuitry and enable signal configuration may be used in combination with the masking circuitry 104 to selectively enable or disable the masking circuitry 104.

Technical effects of the present disclosure may include preserving stability of command words being transmitted to a mode register regardless of a combination of preceding commands being issued based on command decoder masking circuitry. Indeed, the command decoder masking circuitry may disable propagation of unstable mode register control word signals on an output path of the command decoder. By doing so, the command decoder masking circuitry may reduce or eliminate a likelihood of undesired operations occurring in or due to downstream circuits that may otherwise operationally respond to the unstable signals. Masked command signals transmitted from the command decoder masking circuitry, and thus the command decoder, may be transmitted without unstable data or unstable signals. Additionally, these technical improvements may be realized through the command decoder masking circuitry with negligible changes to propagation delays and circuitry footprint within a die or physical space of the memory device.

Although the foregoing discusses various logic low and/or logic high signal polarities, at least some of these polarities may be inverted in some embodiments. Furthermore, in some systems, logic gates as discussed herein may be replaced with one or more logic gates, such as inverters, AND gates, not-AND (NAND) gates, OR gates, not-OR (NOR) gates, or other types of combinational logic.

While the present disclosure may be susceptible to various modifications and alternative forms, specific embodiments have been shown by way of example in the drawings and have been described in detail herein. However, it should be understood that the present disclosure is not intended to be limited to the particular forms disclosed. Rather, the present disclosure is intended to cover all modifications, equivalents, and alternatives falling within the spirit and scope of the present disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]…” or “step for [perform]ing [a function]…”, it is intended that such elements are to be interpreted under 35 U.S.C. 112(f). However, for any claims containing elements designated in any other manner, it is intended that such elements are not to be interpreted under 35 U.S.C.112(f).

What is claimed is:

1. A system, comprising:
a command interface configured to transmit a first command signal and a second command signal via a path at an overlapping time; and
a command decoder coupled to the command interface based on the path, wherein the command decoder comprises:
an output path; and
masking circuitry coupled to the output path comprising:
a first logic gate that receives the first command signal and the second command signal; and
a second logic gate that receives a first output signal from the first logic gate and a third command signal, wherein the second logic gate generates, based on voltages of the first output signal and the third command signal, a masked third command signal.

2. The system of claim 1, comprising a mode register coupled to the command decoder via the output path, wherein the command decoder is configured to transmit the masked third command signal to the mode register via the output path.

3. The system of claim 1, wherein the command decoder and the masking circuitry are disposed on a same die.

4. The system of claim 1, comprising delay circuitry to compensate timing of the first command signal, the second command signal, or both based on a latency added to the masked third command signal based on the masking circuitry.

5. The system of claim 1, comprising a memory controller configured to generate the first command signal and the second command signal sent to the command interface.

6. The system of claim 5, comprising enable circuitry that enables the masking circuitry responsive to an enable signal from the memory controller.

7. The system of claim 6, wherein the memory controller is configured to generate the enable signal based on a determination to reduce metastability in the masked third command signal.

8. The system of claim 5, wherein the memory controller is disposed on a different die than the command decoder.

9. The system of claim 1, wherein the masking circuitry is coupled to an output of the command decoder via an inverter.

10. The system of claim 9, wherein the second logic gate is coupled to a latch that transmits the third command signal.

11. A method comprising:
receiving, via a first logic gate, a first command signal having a logic high voltage level for a first time period;
receiving, via the first logic gate, a second command signal having the logic high voltage level for a second time period, wherein the second time period is at least partially overlapping in time to the first time period;
generating, via the first logic gate, a first output signal;
receiving, via a second logic gate, the first output signal;
receiving, via the second logic gate, a mode register write control word signal; and
generating, via the second logic gate, a second output signal, wherein the second output signal has a falling edge aligned to a rising edge of the second command signal.

12. The method of claim 11, wherein generating the second output signal comprises generating the second output signal with the falling edge and a rising edge that aligns with a rising edge of the first command signal.

13. The method of claim 11, comprising transmitting, via a command decoder output pin, the second output signal to a mode register.

14. The method of claim 11, comprising receiving an enable signal from a controller, wherein the enable signal is configured to enable a first not-AND gate as the first logic gate and a second not-AND gate as the second logic gate.

15. A memory device comprising:
an interface configured to receive one or more command signals; and
masking circuitry comprising one or more logic gates configured to disable propagation of unstable data resulting from unintended signal propagation arising from the one or more command signals.

16. The memory device of claim 15, wherein the interface is configured to receive, as the one or more command signals, an even command signal and an odd command signal, and wherein the masking circuitry comprises:
a first logic gate configured to couple to a first path that receives the even command signal and the odd command signal from the interface, wherein the even command signal has a logic high voltage level for a first time period, wherein the odd command signal has the logic high voltage level for a second time period at least partially overlapping the first time period; and
a second logic gate configured to couple to a latch that generates a mode register write control word signal that receives a first output signal from the first logic gate and a mode register write control word signal, wherein the second logic gate transmits, based on voltages of the first output signal and the mode register write control word signal, a mode register write control word masked output signal without unstable data.

17. The memory device of claim 16, comprising a command decoder, an inverter, and the latch, wherein the second logic gate receives the mode register write control word signal from the latch, and wherein the second logic gate transmits the mode register write control word masked output signal to the inverter.

18. The memory device of claim 17, comprising bank control circuitry configured to generate one or more bank control signals based on the mode register write control word masked output signal from the inverter.

19. The memory device of claim 16, wherein the masking circuitry is located between the interface and bank control circuitry.

20. The memory device of claim 19, wherein the masking circuitry is configured to:
receive, via the first logic gate, the even command signal from the interface;
receive, via the first logic gate, the odd command signal from the interface;
generate, via the first logic gate, the first output signal;
receive, via the second logic gate, the first output signal;
receive, via the second logic gate, the mode register write control word signal;
generate, via the second logic gate, the mode register write control word masked output signal, wherein the mode register write control word masked output signal has a falling edge aligned to a rising edge of the odd command signal; and
transmit, via the second logic gate, the mode register write control word masked output signal to the bank control circuitry.
